(19) United States
(12) Patent Application Publication
(10) Pub. No.: US 2013/0270583 A1
(43) Pub. Date: Oct. 17, 2013

(54) METHOD OF FORMING COPPER WIRING AND METHOD OF MANUFACTURING DISPLAY DEVICE

(71) Applicant: Panasonic Liquid Crystal Display Co., Ltd., (US)

(72) Inventors: Masahiro NAKAGAWA, Hyogo (JP); Makoto YAMAMOTO, Hyogo (JP); Yoshihide ISOBE, Hyogo (JP)

(73) Assignee: Panasonic Liquid Crystal Display Co., Ltd., Himeji-shi (JP)

(21) Appl. No.: 13/859,428

(22) Filed: Apr. 9, 2013

(30) Foreign Application Priority Data
Apr. 13, 2012 (JP) 2012-092154

(51) Int. Cl. H01L 33/00; H01L 21/48

(52) U.S. Cl. CPC H01L 33/0095; H01L 21/4814
USPC 257/88; 438/479; 438/34

(57) ABSTRACT

A method of forming a copper wiring includes forming a copper film on a substrate; forming a resist on the copper film in accordance with a predetermined pattern; forming an oxide film on the copper film on which the resist is formed; etching the copper film on which the oxide film is formed; and removing the resist after the etching of the copper film.

### CROSS-REFERENCE TO RELATED APPLICATION

The present application claims priority from Japanese application JP 2012-092154, the content of which is hereby incorporated by reference into this application.

### BACKGROUND OF THE INVENTION

1. Field of the Invention

The present invention relates to a method of forming a copper wiring and a method of manufacturing a display device.

2. Description of the Related Art

When forming a wiring and an electrode (hereinafter collectively referred to as a “wiring”) of a thin film transistor substrate included in a liquid display device, for example, a photolithography step and an etching step are used. Specifically, for example, after forming a copper film on a glass substrate, the wiring having a predetermined pattern is formed through the photolithography step and the etching step. In the etching step, for example, abnormal etching or so-called pattern thinning sometimes occurs. The abnormal etching causes a central portion of a cross section of the wiring to be concaved. In the pattern thinning, a width of the wiring becomes smaller than needed.

In order to prevent the abnormal etching and the pattern thinning described above, a method using an aqueous solution as an etchant for the copper film is disclosed in Japanese Patent Application Laid-open No. 2001-262374. Specifically, the aqueous solution contains an acid salt such as potassium hydrogen sulfate or ammonium hydrogen sulfate and an oxidizing agent such as hydrogen peroxide.

### SUMMARY OF THE INVENTION

Another wiring, which is formed above the wiring formed in the etching step for the copper film, may be disconnected or may short-circuit, depending on the shape of an end portion of the wiring. For example, when an angle (taper angle) of the end portion of the wiring with respect to a planar direction of a substrate is large, the above-mentioned problem may occur. The occurrence of the problem is specifically described below by referring to FIG. 8, for example.

FIG. 8 illustrates an example of a cross section of a TFT formed on a TFT substrate and a region around the TFT. As illustrated in FIG. 8, in a region where the TFT is to be formed, there are laminated a substrate 801, a gate electrode 802, a gate insulating film 803, a semiconductor layer 804, source and drain electrodes 805, and a passivation film 806 in ascending order in FIG. 8. When a taper angle 808 of a tapered portion 807 at an end of the gate electrode 802 is large, the source and drain electrodes 805 formed above the gate electrode 802 may be disconnected. Moreover, the coverage of the gate insulating film 803 formed on the gate electrode 802 becomes insufficient for the gate electrode 801. As a result, a short-circuit between the gate electrode 802 and the source and drain electrodes 805 may occur.

In view of the problem described above, a main object of one or more embodiments of the present invention is to provide a method of forming a copper wiring including forming an end of a wiring, which is formed in an underlying layer, so as to have a predetermined tapered shape and a method of manufacturing a display device including a substrate having the copper wiring so that another wiring formed above the wiring does not disconnect and short-circuit.

(1) In one or more embodiments of the present invention, a method of forming a copper wiring includes forming a copper film on a substrate; forming a resist on the copper film in accordance with a predetermined pattern; forming an oxide film on the copper film on which the resist is formed; etching the copper film on which the oxide film is formed; and removing the resist after the etching of the copper film.

(2) In the method of forming a copper wiring according to (1), the forming an oxide film may be carried out with O₂ ashing.

(3) In the method of forming a copper wiring according to (1), the forming an oxide film may be carried out using a hydrogen peroxide solution.

(4) In the method of forming a copper wiring according to one of (1) to (3), the method may further includes removing an upper portion of the oxide film after the forming of the oxide film.

(5) In the method of forming a copper wiring according to (4), in the removing an upper portion of the oxide film, an amount of removal of the oxide film may be larger for a thicker portion of the oxide film.

(6) In the method of forming a copper wiring according to (4), in the removing an upper portion of the oxide film, only a portion of the oxide film, which is formed above a central part of the substrate, may be removed.

(7) In the method of forming a copper wiring according to claim 4, in the removing an upper portion of the oxide film, an amount of removal of a portion of the oxide film in a thickness direction of the oxide film, which is formed above a central part of the substrate, may be different from an amount of removal of a portion of the oxide film in the thickness direction of the oxide film, which is formed above a peripheral part of the substrate.

(8) In the method of forming a copper wiring according to (7), in the removing an upper portion of the oxide film, the amount of the removal of the portion of the oxide film, which is formed above the central part of the substrate, may be larger than the amount of the removal of the portion of the oxide film, which is formed above the peripheral part of the substrate.

(9) In the method of forming a copper wiring according to one of (4) to (8), the removing an upper portion of the oxide film may be carried out with argon plasma processing.

(10) In the method of forming a copper wiring according to one of (1) to (9), the method may further includes forming an insulating film on the substrate from which the resist is removed; and forming a semiconductor layer and a metal film on the insulating film in this order.

(11) In the method of forming a copper wiring according to one of (1) to (10), the substrate may includes a plurality of TFT substrates.

(12) In one or more embodiments of the present invention, a display device includes a wiring substrate manufactured by the method of forming a copper wiring according to (1) to (11).

(13) In one or more embodiments of the present invention, a method of manufacturing a display device including a substrate, includes forming a copper film on the substrate; forming a resist on the copper film in accordance with a predetermined pattern; forming an oxide film on the copper film on which the resist is formed; etching the copper film on which the oxide film is formed; and removing the resist after the etching of the copper film.

### BRIEF DESCRIPTION OF THE DRAWINGS

In the accompanying drawings:

FIG. 1 is a schematic view illustrating a display device according to an embodiment of the present invention;

FIG. 2 is a conceptual diagram illustrating a pixel circuit formed on a TFT substrate;

FIG. 3 is a diagram illustrating a schematic top surface of a pixel region of the TFT substrate;

FIG. 4 is a diagram illustrating a schematic cross section taken along the line IV-IV of FIG. 3;

FIG. 5A is a diagram illustrating a method of manufacturing the display device;

FIG. 5B is another diagram illustrating the method of manufacturing the display device;

FIG. 5C is another diagram illustrating the method of manufacturing the display device;

FIG. 5D is another diagram illustrating the method of manufacturing the display device;

FIG. 5E is another diagram illustrating the method of manufacturing the display device;

FIG. 5F is another diagram illustrating the method of manufacturing the display device;

FIG. 6 is a diagram illustrating side etching of a gate electrode layer;

FIG. 7 is a graph showing an ashing-rate distribution in mother glass; and

FIG. 8 is a diagram illustrating a problem to be solved by the present invention.

### DETAILED DESCRIPTION OF THE INVENTION

In the following, an embodiment of the present invention is described referring to the accompanying drawings. In the drawings, the same or equivalent components are denoted by the same reference numerals, and the overlapping description thereof is herein omitted.

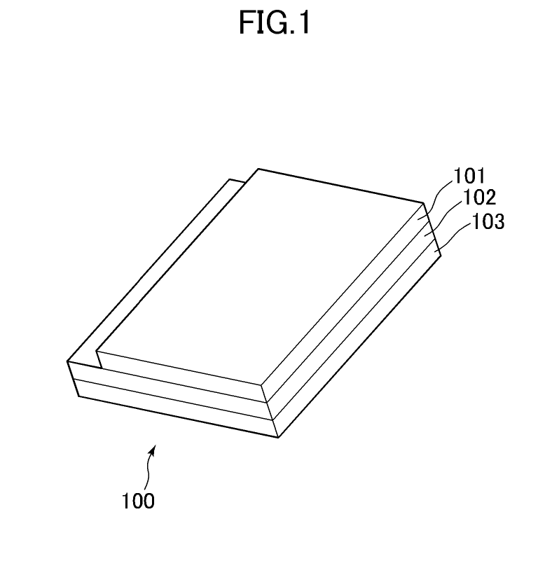

FIG. 1 is a schematic diagram illustrating a display device according to an embodiment of the present invention. As illustrated in FIG. 1, a display device 100 includes, for example, a thin film transistor (TFT) substrate 102 and a filter substrate 101. On the TFT substrate 102, TFTs and the like (not shown) are formed. The filter substrate 101 is opposed to the TFT substrate 102 and is provided with color filters (not shown). The display device 100 also includes a liquid crystal material (not shown) and a backlight unit 103. The liquid crystal material is sealed in a region sandwiched between the TFT substrate 102 and the filter substrate 101. The backlight unit 103 is provided on the TFT substrate 102 so as to be held in contact with a surface opposite to the side on which the filter substrate 101 is provided.

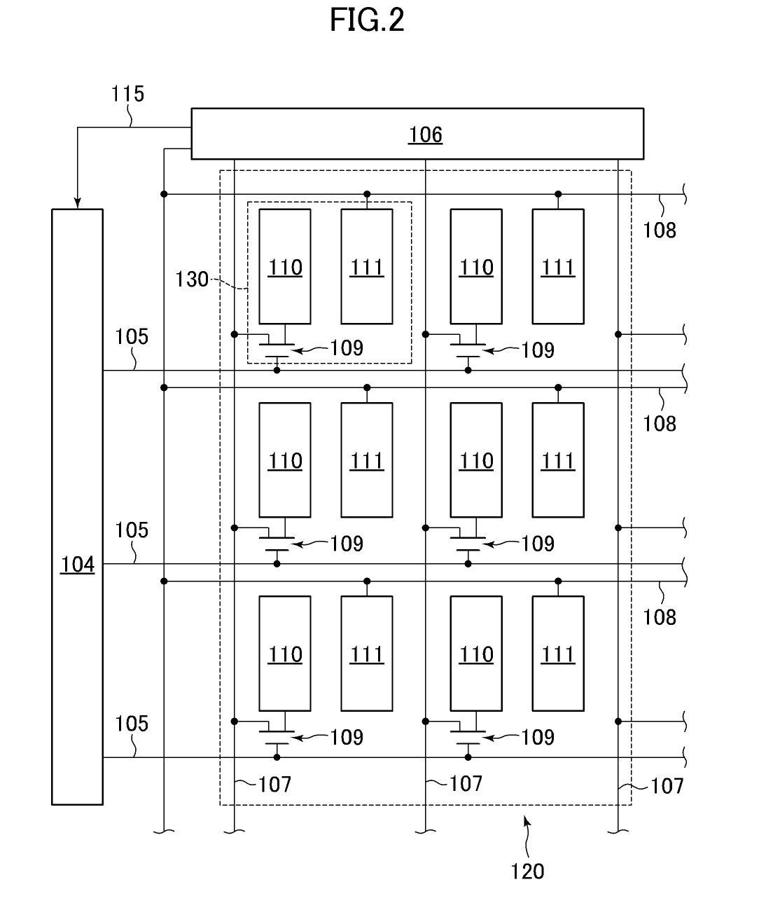

FIG. 2 is a conceptual diagram of a pixel circuit formed on the TFT substrate 102 illustrated in FIG. 1. As illustrated in FIG. 2, the TFT substrate 102 includes a plurality of gate signal lines 105 and a plurality of video signal lines 107. The gate signal lines 105 are horizontally arranged at approximately equal intervals. The video signal lines 107 are vertically arranged at approximately equal intervals . The gate signal lines 105 are connected to a shift register circuit 104, whereas the video signal lines 107 are connected to a driver 106.

The shift register circuit 104 includes a plurality of basic circuits (not shown) respectively corresponding to the plurality of gate signal lines 105. Each of the basic circuits includes a plurality of TFTs and capacitors. Each of the basic circuits outputs a gate signal to a corresponding one of the gate signal lines 105 in response to a control signal 115 from the driver 106. A voltage of the gate signal becomes high during a corresponding gate scanning period (HIGH-signal period) of one frame period and becomes low during the remaining period (LOW-signal period).

Pixel regions 130 are formed in a matrix pattern by partition with the gate signal lines 105 and the video signal lines 107. Each of the pixel regions 130 includes a TFT 109, a pixel electrode 110, and a common electrode 111. A gate of the TFT 109 is connected to a corresponding one of the gate signal lines 105. One of a source and a drain is connected to a corresponding one of the video signal lines 107, whereas the other one is connected to the pixel electrode 110. The common electrode 111 is connected to a corresponding one of common signal lines 108. The pixel electrode 110 and the common electrode 111 are provided so as to be opposed to each other.

Next, a schematic operation of the pixel circuit configured as described above is described. The driver 106 applies a reference voltage to the common electrodes 111 through the common signal lines 108. The shift register circuit 104 controlled by the driver 106 outputs a gate signal to the gate of the TFTs 109 through the gate signal lines 105. Further, the driver 106 supplies a voltage of the video signal to the TFTs 109, to which the gate signal is output, through the video signal lines 107. The voltage of the video signal is applied to the pixel electrodes 110 through the TFTs 109. At this time, potential differences are generated between the pixel electrodes 110 and the common electrodes 111.

The driver 106 controls the potential differences to control the orientation of liquid crystal molecules of the liquid crystal material inserted between the pixel electrodes 110 and the common electrodes 111. Light from the backlight unit 103 is guided to the liquid crystal material. Therefore, by controlling the orientation of the liquid crystal molecules as described above, the amount of light from the backlight unit 103 can be adjusted. As a result, an image can be displayed.

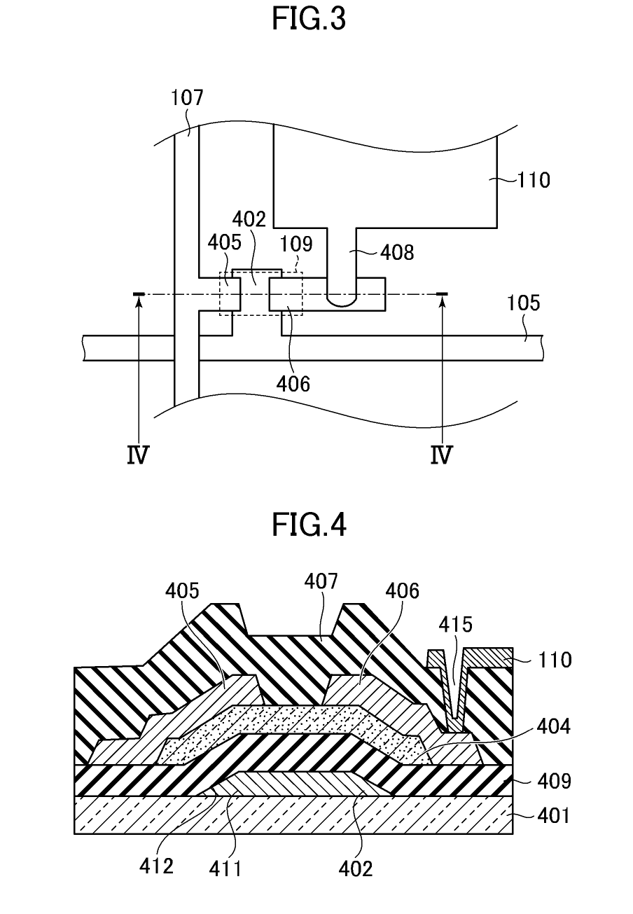

FIG. 3 is a diagram illustrating a schematic top surface of a pixel region of the TFT substrate 102. The top diagram of the TFT substrate 102 illustrated in FIG. 3 is merely an example, and therefore this embodiment is not limited thereto. As illustrated in FIG. 3, for example, in a peripheral portion where the gate signal line 105 and the video signal line 107 intersect, the TFT 109 is formed. The TFT 109 includes a gate electrode 402, a semiconductor layer (not shown), a drain electrode 405, and a source electrode 406. The gate electrode 402 is formed so as to extend from the gate signal line 105. The semiconductor layer is provided above the gate electrode 402. The drain electrode 405 and the source electrode 406 are provided on the semiconductor layer. The drain electrode 405 corresponds to, for example, a part of the video signal line 107. The source electrode 406 is connected to the pixel electrode 110 through a wiring portion 408.

FIG. 4 is a diagram illustrating a schematic cross section taken along the line IV-IV of FIG. 3. As illustrated in FIG. 4, the gate electrode 402 is provided on a region of a substrate 401, on which the TFT 109 is to be formed. A gate insulating film 409 is provided so as to cover the substrate 401 on which the gate electrode 402 is provided.

On the gate insulating film 409, a semiconductor layer 404 is formed so as to overlap at least a part of the gate electrode 402 as viewed from above in FIG. 4. The source electrode 406 and the drain electrode 405 are provided on the semiconductor layer 404. A source/drain electrode layer, which forms the source electrode 406 and the drain electrode 405, is made of the same material, for example, Cu.

A passivation film 407, which is formed on the source electrode 406 and the drain electrode 405, includes a contact hole 415 through which the pixel electrode 110 is connected to the source electrode 406. Specifically, the wiring portion 408 of the pixel electrode 110 is provided on the passivation film 407 so as to cover a region including the contact hole 415, thereby connecting the pixel electrode 110 to the source electrode 406.

As a material of the gate insulating film 409 and the passivation film 407, SiN is used, for example . As a material of the semiconductor layer 404, a-Si is used. As the substrate 401, for example, a glass substrate is used. Moreover, besides Cu, Mo, W, Al, a Cu—Al alloy, and the like may be used as a material of the source/drain electrode layer and the gate electrode 402. As a material of the pixel electrode 110, for example, indium tin oxide (ITO) is used.

As illustrated in FIG. 4, the gate electrode 402 of this embodiment includes tapered portions 411 on both ends. The gate electrode 402 has a gradually increasing width as viewed from above the substrate 401 because of the tapered portions 411. Each of the tapered portions 411 has a sufficiently small taper angle 412 so that the gate insulating film 409 formed on the tapered portions 411 is not short-circuited with the semiconductor layer 404, the source electrode 406, or the drain electrode 405, which is formed above the tapered portions 411, and the disconnection does not occur in the source electrode 406 and the drain electrode 405, which are formed above the tapered portions 411.

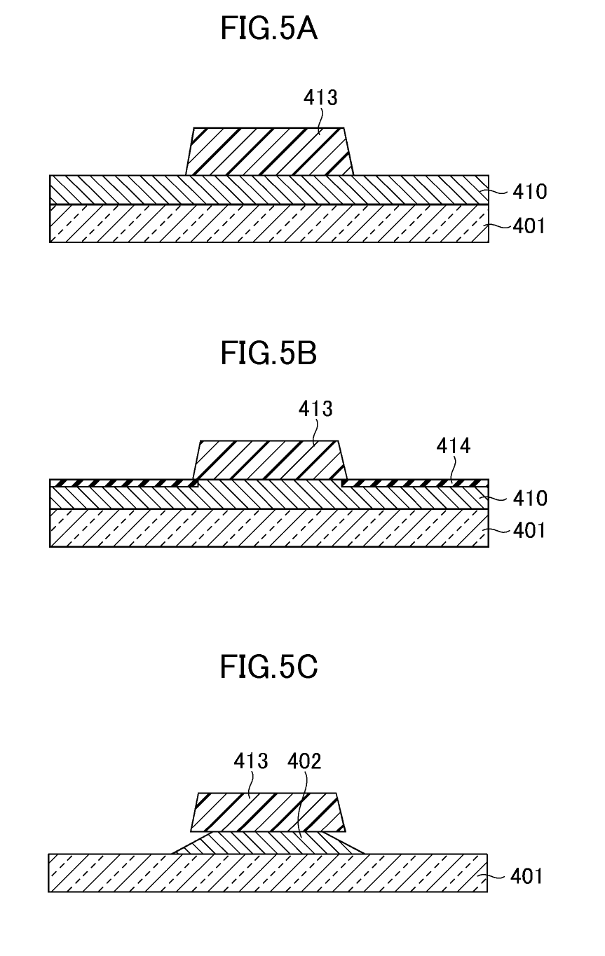

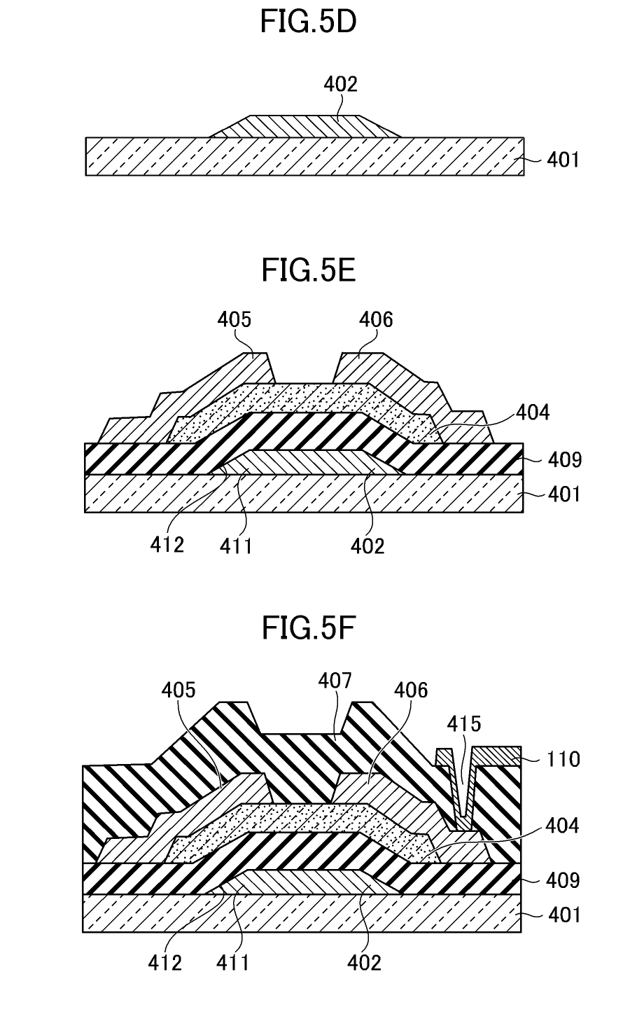

A method of manufacturing the display device 100 according to this embodiment is now described. FIGS. 5A to 5F are diagrams illustrating the method of manufacturing the display device 100 according to this embodiment. In the following, as an example, there is described the case where a so-called multiple-pattern method of forming a plurality of the TFT substrates 102 on a large-sized substrate that is called mother glass.

As illustrated in FIG. 5A, on the substrate 401, a gate electrode layer 410 for forming the gate electrode 402 is formed by, for example, sputtering. As a material of the gate electrode layer 410, Cu is used. Next, a resist 413 is applied onto the gate electrode layer 410 and is then exposed by using a mask having a predetermined pattern. Next, an unnecessary portion of the resist 413 is removed.

Next, as illustrated in FIG. 5B, a Cu oxide film 414 is formed by O₂ ashing on the gate electrode layer 410 on which the resist 413 is formed in accordance with the predetermined pattern. A step of forming the Cu oxide film 414 may be carried out using, for example, a hydrogen peroxide solution.

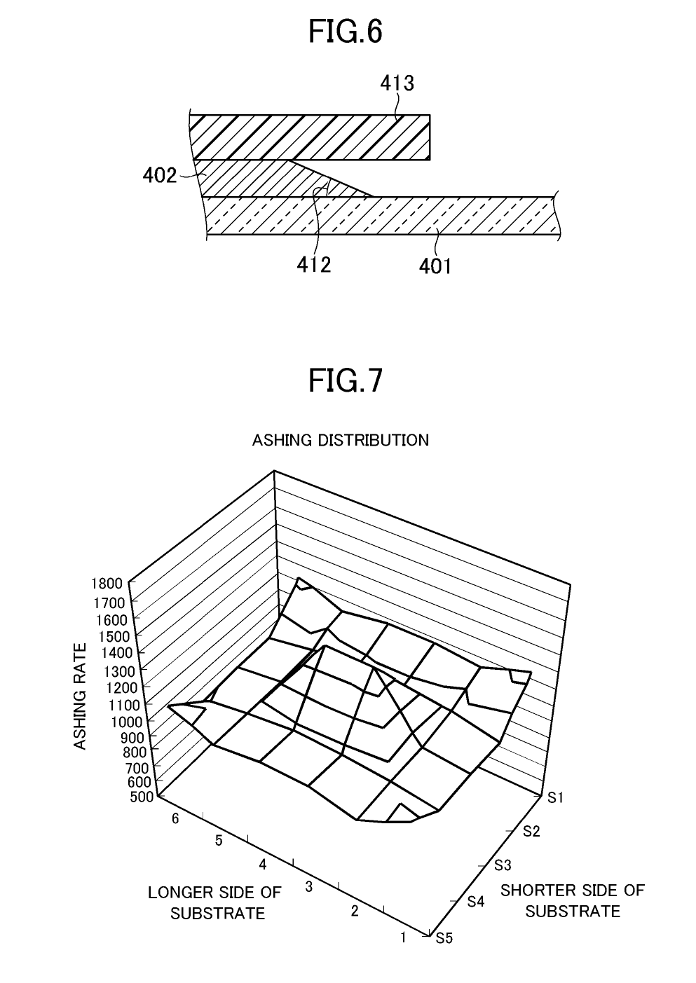

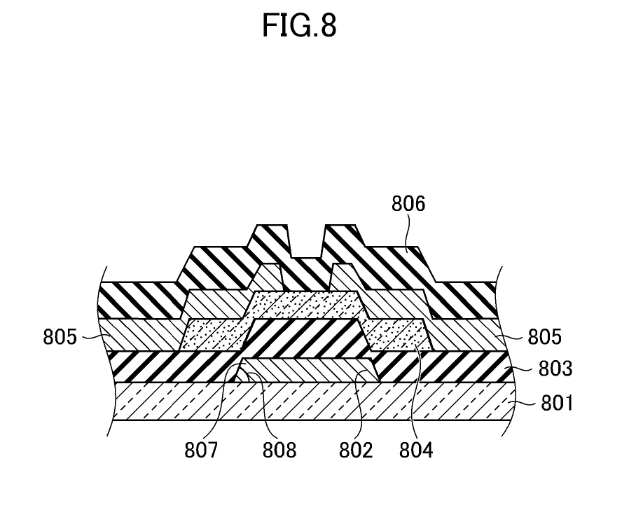

Next, as illustrated in FIG. 5C, the gate electrode layer 410 is processed into an island-like shape by etching. Specifically, the gate electrode layer 410 illustrated in FIG. 5B, on which the Cu oxide film 414 is formed, is etched. At this time, the Cu oxide film 414 is formed on the gate electrode layer 410. Therefore, side etching of the gate electrode layer 410 proceeds excessively as illustrated in FIG. 6 as compared with the case where the Cu oxide film 414 is not formed. As a result, as illustrated in FIG. 6, each of ends of the gate electrode 402 can be formed into a forward tapered shape so that the gate electrode 402 has a gradually increasing width toward the substrate 401 as viewed from above the substrate 401, while the taper angle 412 of each of the tapered portions 411 can be reduced as compared with the case where the Cu oxide film 414 is not formed. A state of a periphery of the gate electrode layer 410 at this time is illustrated in FIG. 5C.

Next, as illustrated in FIG. 5D, the resist 413 is removed to form the gate electrode 402.

FIG. 7 is a graph showing an ashing-rate distribution in mother glass. In FIG. 7, a z-direction axis indicates an ashing rate, an x-direction axis represents a long side of the mother glass (substrate), and a y-direction axis represents a short side of the mother glass. As shown in FIG. 7, in the O₂ ashing described above, the ashing proceeds excessively in a central part of the mother glass. Therefore, after the O₂ ashing, an upper portion of the Cu oxide film 414 formed by the O₂ ashing may be removed, for example, by Ar sputtering so that the Cu oxide film 414 becomes more uniform over the entire mother glass. Specifically, the amount of removal of the upper portion of the Cu oxide film 414 may be set large for the central part of the mother glass as compared with that for the remaining part (peripheral part) of the mother glass. In other words, time for conducting the Ar sputtering may be set longer for the central part of the mother glass. Alternatively, for example, the amount of removal of the Cu oxide film 414 may be set larger for a thicker portion of the Cu oxide film 414. Further alternatively, the Cu oxide film 414 formed above the central part of the mother glass may be removed without removing the portion of the Cu oxide film 414 formed above the peripheral part of the mother glass. In this manner, a width of the wiring (including the electrodes) formed above the central part of the mother glass, for example, the gate electrode 402, can be prevented from becoming thinner than needed. In other words, the width of the wiring included in each of the TFT substrates 102, for example, the gate electrode 402, can be more uniform.

Next, as illustrated in FIG. 5E, the gate insulating film 409 is formed by, for example, CVD to form the semiconductor layer 404. Then, through the photolithography step and the etching step, the semiconductor layer 404 forming the TFT is formed so as to have a predetermined shape. Next, the source/drain electrode layer is formed by sputtering. Then, through the photolithography step and the etching step, the source/drain electrode is processed so as to have a predetermined shape. In this manner, the source electrode 406 and the drain electrode 405 are formed.

Next, as illustrated in FIG. 5F, the passivation film 407 is formed on the substrate 401 on which the source electrode 406 and the drain electrode 405 are formed as described above. Then, through the photolithography step and the etching step, the contact hole 415 is formed in a region where the contact hole 415 is to be formed. Next, a metal film for forming the pixel electrode 110 is formed by sputtering. Then, the metal film is processed through the photolithography step and the etching step to form the pixel electrode 110.

Thereafter, the mother glass is cut into the plurality of the TFT substrates 102. Then, the filter substrate 101, which is manufactured separately, is bonded to each of the TFT substrates 102 obtained by cutting so as to interpose a liquid crystal layer therebetween. Further, the backlight unit 103 and the like are mounted to form the display device 100.

According to the embodiment described above, the copper wiring having the tapered portions 411, each having the predetermined taper angle 412, can be formed on the substrate 401. As a result, the disconnection or the short-circuit in the wiring or the electrodes formed above the copper wiring can be effectively prevented. Specifically, the gate electrode 402 having the sufficiently small taper angles 412 at both ends can be formed on the substrate 401. Therefore, the disconnection of the source electrode 406 and the drain electrode 405, which are formed above the tapered portions 411, and the short-circuit between the gate electrode 402 and the semiconductor layer 404, the source electrode 406, or the drain electrode 405 can be effectively prevented.

The present invention is not limited to the embodiment described above. The configuration described in the embodiment may be replaced by substantially the same configuration as the configuration described above in the embodiment, a configuration having the same functions and effects, or a configuration enabling the achievement of the same object. For example, in the description given above, the method of forming the copper wiring on the TFT substrate used for the liquid crystal display device has been mainly described as an example. However, the present invention is not limited thereto. For example, the present invention may be applied to a method of forming a wiring on a substrate of a display device using various types of light-emitting elements such as organic EL elements, inorganic EL elements, and field-emission devices (FED), a method of manufacturing a display device on which the wiring is formed, a method of forming a wiring on a substrate of other types of electronic equipment, and a method of manufacturing the electronic equipment. Further, in the description given above, an inverted staggered TFT has been mainly described. However, the form of the TFT is not limited thereto. The TFT may be a staggered TFT or other types of TFTs.

What is claimed is:

1. A method of forming a copper wiring, comprising:
forming a copper film on a substrate;
forming a resist on the copper film in accordance with a predetermined pattern;
forming an oxide film on the copper film on which the resist is formed;
etching the copper film on which the oxide film is formed; and
removing the resist after the etching of the copper film.

2. The method of forming a copper wiring according to claim 1, wherein the forming an oxide film is carried out with O₂ ashing.

3. The method of forming a copper wiring according to claim 1, wherein the forming an oxide film is carried out using a hydrogen peroxide solution.

4. The method of forming a copper wiring, according to claim 1, further comprising removing an upper portion of the oxide film after the forming of the oxide film.

5. The method of forming a copper wiring according to claim 4, wherein, in the removing an upper portion of the oxide film, an amount of removal of the oxide film is larger for a thicker portion of the oxide film.

6. The method of forming a copper wiring according to claim 4, wherein, in the removing an upper portion of the oxide film, only a portion of the oxide film, which is formed above a central part of the substrate, is removed.

7. The method of forming a copper wiring according to claim 4, wherein, in the removing an upper portion of the oxide film, an amount of removal of a portion of the oxide film in a thickness direction of the oxide film, which is formed above a central part of the substrate, is different from an amount of removal of a portion of the oxide film in the thickness direction of the oxide film, which is formed above a peripheral part of the substrate.

8. The method of forming a copper wiring according to claim 7, wherein, in the removing an upper portion of the oxide film, the amount of the removal of the portion of the oxide film, which is formed above the central part of the substrate, is larger than the amount of the removal of the portion of the oxide film, which is formed above the peripheral part of the substrate.

9. The method of forming a copper wiring according to claim 4, wherein the removing an upper portion of the oxide film is carried out with argon plasma processing.

10. The method of forming a copper wiring according to claim 1, further comprising:
forming an insulating film on the substrate from which the resist is removed; and
forming a semiconductor layer and a metal film on the insulating film in this order.

11. The method of forming a copper wiring according to claim 1, wherein the substrate includes a plurality of TFT substrates.

12. A display device, comprising a wiring substrate manufactured by the method of forming a copper wiring according to claim 1.

13. A method of manufacturing a display device including a substrate, comprising:
forming a copper film on the substrate;
forming a resist on the copper film in accordance with a predetermined pattern;
forming an oxide film on the copper film on which the resist is formed;
etching the copper film on which the oxide film is formed; and
removing the resist after the etching of the copper film.
